(19) United States
(12) Patent Application Publication
(10) Pub. No.: US 2004/0114681 A1
(43) Pub. Date: Jun. 17, 2004

(54) Method for improving performance of wireless systems at high speeds

(76) Inventors: Ron Rotstein, Arlington Heights, IL (US); Randy L. Ekl, Lake Zurich, IL (US); Mark J. Johnson, Cary, IL (US)

Correspondence Address: MOTOROLA, INC., 1303 EAST ALGONQUIN ROAD, IL01/3RD, SCHAUMBURG, IL, 60196

(21) Appl. No.: 10/321,883

(22) Filed: Dec. 17, 2002

(51) Int. Cl. H03H 7/30; H03H 7/40; H04B 1/10

(52) U.S. Cl. 375/231; 375/232; 375/350

(57) ABSTRACT

In a system that uses equalization signaling to determine at least one equalization parameter representative of at least one property of a channel, a signal is received on the channel. A rate of change of the at least one property of the channel is estimated. Based on the rate of change of the at least one property of the channel, the equalization signaling is adjusted.

### FIELD OF THE INVENTION

The present invention relates generally to wireless data communication devices, and is especially applicable to mobile devices operating at vehicular speeds.

### BACKGROUND OF THE INVENTION

Wireless systems, especially digital wireless systems, operate in an environment that is in many ways less predictable than their wired counterparts. Signals in a range of frequencies (band) are affected by numerous physical and electromagnetic phenomena. Received signal levels, signal-to-noise ratios, frequency offsets and frequency errors are extremely variable, the phase of the received signal is effectively arbitrary and varies over time, and phenomena such as gain, attenuation, multipath, fading, signal blocking obstacles, and antenna location and orientation contribute to the propagation characteristics of the channel. The problem is exacerbated as the bandwidth of the signal increases, since different frequency ranges or sub-bands within the overall band may exhibit significantly different propagation characteristics. Many high-bandwidth signals are comprised of multiple data streams sent in narrower sub-bands within the overall band occupied by the signal. The sum of all of the propagation effects affecting the signal is referred to as a channel, and the set of propagation effects affecting only that part of a signal in a sub-band is referred to as a sub-channel.

Many such systems use equalization to compensate for these effects. An equalizing receiver measures the characteristics of a signal received through the channel and, based on known characteristics of the transmitted signal, infers a model (estimation) of the effects of propagation through the channel called a channel model (or channel estimation). Such a system then applies filtering and/or sub-channel selection in order to compensate for the channel characteristics and optimize the communication through the channel. This channel model substantially represents the channel properties only for a limited duration herein referred to as the “coherence time” due to changes in the environment as well as in the location and orientation of the devices involved.

In lower speed systems, the equalization can often be updated incrementally if the rate of change of the propagation environment is low compared to the symbol rate. However, if the signaling speed of the system is comparatively high, it is impractical to perform this type of compensation. In such systems, predetermined signaling called equalization signaling is used. In one example, an initial propagation model is established using equalization signaling referred to as a “training sequence” and the maximum duration of a transmission is constrained to the estimated coherence time. In the case of the 802.11a standard, the training sequence is comprised of two parts, a short training sequence which is an analog signal used to establish an approximate channel model, and a long training sequence which is a predetermined data sequence used to further refine the channel model established by the short training sequence. The estimated coherence time is based on assumptions including the characteristics of the frequency band of the channel, the propagation environment, and the design and behavior of devices communicating on the channel. Many systems in the prior art augment the estimated coherence time by supplying another form of equalization signaling referred to as “pilots.” Pilots are signals that are transmitted simultaneously or interleaved with a data signal, but whose transmitted modulation is known a priori by devices in the system. The pilots may be transmitted in specific sub-channels and analyzed by receivers to provide ongoing estimates of slowly varying changes affecting payload sub-channels near the pilot sub-channel. Examples of systems using both training sequences and pilot-based equalization estimation include wireless local area network (“WLAN”) systems such as 802.11a, which breaks down a 20 MHz channel into sixty-four individual 312.5 KHz sub-channels. Fifty-two of these sub-channels are actively used in signaling (the remainder are reserved as a guard band). Four of the fifty-two active sub-channels are used for pilot signals, with measured effects on the pilot channel representing estimated channel effects on twelve payload sub-channels (six on each side). Given this configuration, the spectral distance from a pilot to a sub-channel represented by that pilot may be up to 1.875 MHz.

Although adding pilots can extend the coherence time of the propagation model in systems moving at low (walking) speeds, it is less effective at higher speeds, such as vehicular speeds. When one of the devices is moving at a high speed relative to the other, or relative to obstacles in the propagation environment, not only does the overall channel change much more rapidly, but the individual sub-channels change more rapidly relative to each other, invalidating the implicit assumption that the changes in a pilot sub-channel are representative of the changes in sub-channels nearly 2 MHz distant. In such an environment, the spectral distance between the pilot sub-channel and a sub-channel that can be accurately represented by characterization of the pilot sub-channel is significantly reduced. For this reason, current wideband implementations are generally designed only for stationary or pedestrian-speed operation and do not perform well when moving at or above vehicular speeds.

These issues can be addressed in the design of a system by shortening the duration of transmissions to the coherence time of the channel model at higher speeds (thereby increasing the frequency of training sequence transmission), or by dedicating additional sub-bands to pilots in order to reduce the maximum spectral distance between the pilots and the other sub-bands they are assumed to represent. Both of these approaches, however, have a significant performance impact on all users. Training sequences use time that would otherwise be available for user payload, and increasing the number of pilot sub-bands reduces the number of available payload sub-bands. This penalizes all users of the system in order to better support those few users who are moving at higher speeds, and proportionally reduces the overall system capacity. The impacts of such design tradeoffs are considered unacceptable in most current systems other than those exclusively or primarily intended for highly mobile use.

Thus, there exists a need for a method of adaptively equalizing a high-speed channel at a rate sufficient for highly mobile users without significantly impacting the performance experienced by stationary or slowly moving users.

### BRIEF DESCRIPTION OF THE FIGURES

The features of the present invention are set forth with particularity in the appended claims. The invention, together with its preferred embodiments, may be best understood by reference to the accompanying drawings in which:

FIG. 1 illustrates an environment in which a portable (stationary or slow-moving) device and a mobile (fast-moving) device are in communication with a fixed device;

FIG. 2 illustrates the different effects on a channel model when the fixed device communicates with the portable device and when the fixed device communicates with the mobile device;

FIG. 3 illustrates the effects on the channel model when the fixed device communicates with the mobile device in accordance with the preferred embodiment of the present invention; and

FIG. 4 illustrates a flow chart detailing a process of dynamically negotiating the coherence time parameter between the mobile device and the fixed device in accordance with the preferred embodiment of the present invention.

### DETAILED DESCRIPTION OF THE PREFERRED EMBODIMENT

It will be appreciated that for simplicity and clarity of illustration, elements shown in the figures have not necessarily been drawn to scale. For example, the dimensions of some of the elements are exaggerated relative to each other. Further, where considered appropriate, reference numerals have been repeated among the figures to indicate identical elements.

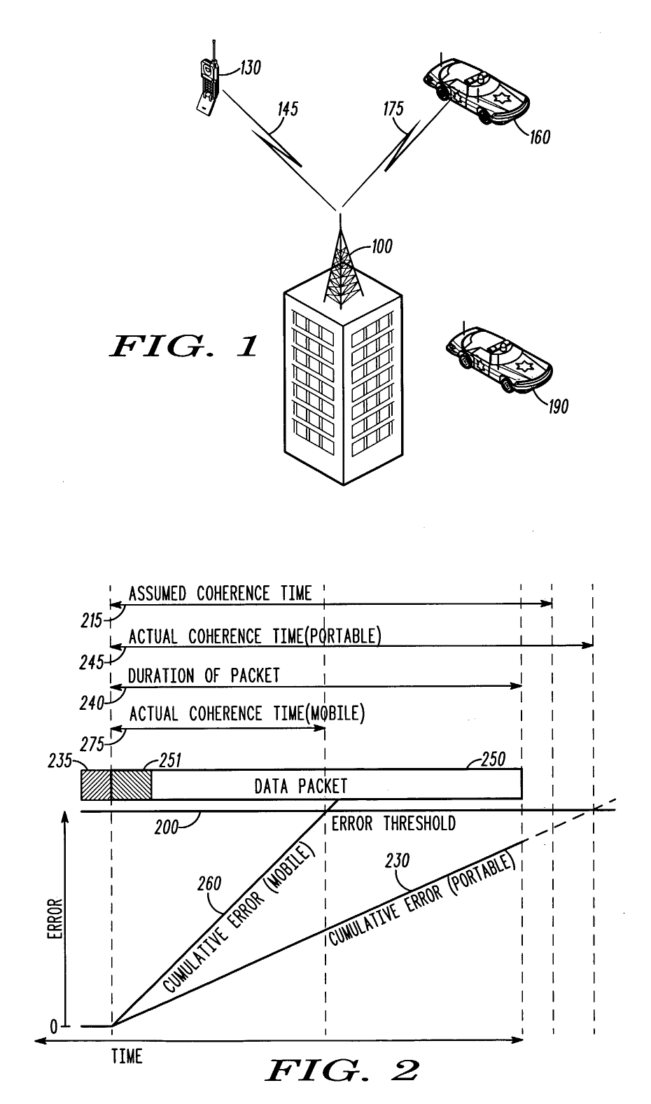

Referring now to FIG. 1, an example of an environment where the present invention produces an improvement over the prior art is illustrated. In this example, a fixed device 100 (such as an access point, or AP) is shown communicating with a portable device 130 through a channel 145. The channel 145 imposes all propagation effects on a signal transmitted from the portable device 130 to the fixed device 100. The channel 145 may change over time due to changing environmental conditions. The portable device 130 is assumed to be moving at a low speed, for example less than 10 miles per hour (“mph”), relative both to its environment and to the fixed device 100. Also shown in FIG. 1 is a mobile device 160 that is also in communication with the fixed device 100 through a channel 175. The mobile device 160 is assumed to be traveling at vehicular speeds, for example 30 mph or greater, relative either to its environment or to the fixed device 100. The channel 175 imposes all propagation effects on a signal transmitted from the mobile device 160 to the fixed device 100. The channel 175 is expected to change much more rapidly than the channel 145 due to the higher speed of the mobile device 160 compared to that of the portable device 130. The present invention accommodates the more stringent equalization requirements of the channel 175 without imposing an unnecessary overhead burden on the portable device 130 using the more tractable channel 145. Although this example, for purposes of simplicity, uses the model of communication between a fixed device 100 and movable devices 130, 160, it will be clear to those skilled in the art that the present invention is equally applicable to communications between the mobile device 160 and the portable device 130, or to communications between a first mobile device 160 and a second mobile device 190.

Referring now to FIG. 2, the coherence time issue is illustrated by showing the cumulative error 230 over time in the channel model representing the channel between the portable device 130 and the fixed device 100. The portable device 130 initially sends a training sequence 235, which allows the characterization of the channel 145 by the fixed device 100. Due to this characterization, the cumulative error 230 in the model of the channel 145 by the fixed device 100 is substantially zero at the end of the training sequence 235. A data packet 250 of a given duration 240, the initial portion of which contains the message header 251, follows the training sequence 235. In the design of the signaling protocol, the maximum duration of the data packet 250 is specified to be less than or equal to the assumed coherence time 215 of the system. When the cumulative error 230 exceeds the error threshold 200, the actual coherence time 245 of the channel model 145 is reached, and further data will be lost; therefore the packet 250 will be properly decoded only if its duration 240 is less than or equal to the actual coherence time 245. When the system is operating within its design parameters, the assumed coherence time 215 will be less than or equal to the actual coherence time 245, and the duration 240 of the packet 250 will be less than or equal to the assumed coherence time 215 (which is generally expressed as a specified maximum packet duration); therefore, the duration 240 of the packet 250 will be less than the actual coherence time 245.

Because of the greater speed of the mobile device 160, the cumulative error 260 of the model representing the channel 175 between the mobile device 160 and the fixed device 100 increases at a faster rate. One of the issues addressed by the present invention is illustrated with an example wherein the mobile device 160 attempts to transmit a packet 250 that is substantially identical to the packet 250 transmitted by the portable device 130, but while traveling at a higher rate of speed. The mobile device 160, like the portable device 130 in the previous example, also initially sends a training sequence 235, which allows the characterization of the channel 175 by the fixed device 100. Due to this characterization, the cumulative error 260 in the characterization of the channel 175 by the fixed device 100 is substantially zero at the end of the training sequence 235. The data packet 250 of duration 240, the initial portion of which contains the message header 251, follows the training sequence 235. When the cumulative error 260 exceeds the error threshold 200, the actual coherence time 275 of the propagation model of the channel 175 is reached. This actual coherence time 275 is likely to be shorter than the assumed coherence time 215 if the default system parameters were not explicitly chosen to accommodate the higher speed of the mobile device 160. If the actual coherence time 275 is shorter than the duration 240 of the data packet 250, the error threshold 200 will be exceeded before the data packet 250 is completed and the data packet 250 is unlikely to be properly decoded by the fixed device 100. In the present art, the failure of the fixed device 100 to properly decode and acknowledge the packet 250 will in many cases result in a second transmission of the packet 250, but unless the conditions of the channel 175 have substantially improved, it is unlikely that another substantially identical transmission will be any more successful than the first. The present invention takes steps to improve the probability of successful delivery of the packet 250 on subsequent attempts.

The preferred embodiment of the present invention allows an equalization system optimized for a base set of environmental assumptions, including, for instance, that users will be stationary or moving at low speeds, to extend its range of operation beyond those initial assumptions. Unlike the current art, in which failed packets are retransmitted without modification, the present invention enables devices to dynamically sense channel conditions and request changes to the message format to improve the likelihood of successful delivery. The changing of the message format is accomplished in a way that improves the performance for devices experiencing harsh channel conditions without penalizing users whose channel conditions are compliant with the assumed system environment. Specifically, the improvement is achieved by increasing the amount of equalization signaling only on channels which will not perform adequately with the equalization signaling designed for the base set of environmental assumptions.

In accordance with the present invention, it has been determined that the actual coherence duration 275 is less than the duration 240 of the packet 250. It is assumed in this example that, as described in the discussion of FIG. 2, the first transmission of the packet 250 failed due to the decreased coherence time of the channel. However, if the actual coherence time 275 is greater than the duration of the message header 251, which contains information including the identity of the device sending the packet, the fixed device 100 can ascertain the identity of the mobile device 160. With this information, the fixed device 100 can instruct the mobile device 160 to modify its equalization signaling to improve the chances of successful delivery of the packet 250.

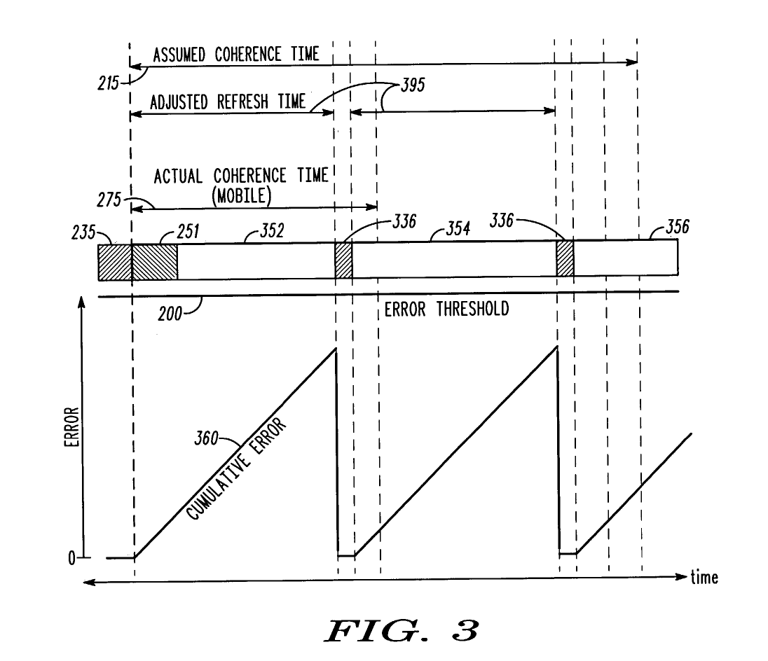

Referring to FIG. 3, a retransmission of the packet 250 is illustrated in conformance with the present invention. Once the actual coherence time 275 of the channel 175 has been determined to be shorter than the duration 240 of the data packet 250, the fixed device 100 takes steps to ensure that the format of the packet 250 is modified such that the cumulative error 360 does not exceed the error threshold 200 during transmission of the data packet 250 in accordance with the preferred embodiment of the present invention. The fixed device 100 transmits a parameter specifying an adjusted refresh time (“ART”) 395 to the mobile device 160. The ART 395 is less than the duration of the data packet 250, since the actual coherence time 275 is assumed to be less than the duration 270 of the data packet 250; if the actual coherence time 275 were greater than the duration 270 of the packet 250, it is assumed that the data packet 250 would have been correctly decoded (if sophisticated methods to determine the actual coherence time 275 of the channel 175 are used, the ART 395 may be set preemptively even if the packet is correctly decoded).

A universal method of setting the ART 395 is, when a packet fails, to set the value of the ART 395 to a fraction of the lesser of (1) the ART currently being used, or (2) the duration 240 of the failed packet, since if either the current ART or the packet duration is less than the actual coherence time 275 of the channel 175, the packet should be correctly decoded. For purposes of illustration, the preferred embodiment sets the ART 395 in the present example to forty percent of the duration of the data packet 250. The parameter specifying the ART 395 is preferably transmitted as a control message from the fixed device 100 to the mobile device 160 and kept as short as possible to improve the chances of successful delivery through the channel 175.

The mobile device 160 responds to the control message by breaking the data packet 250 into data blocks 352, 354, 356 of duration less than or equal to the ART 395 for retransmission. As in the previous unsuccessful transmission, the mobile device 160 sends a training sequence 235, which allows the characterization of the channel by the fixed device 100. The characterization of the channel 175 by the fixed device 100 allows the cumulative error to be substantially zero at the end of the initial training sequence 235.

The training sequence 235 is followed by the segment 352 of the data packet 250, during which the cumulative error 360 increases. After the segment 352 is complete, an incremental training sequence 336 is transmitted. The incremental training sequence 336 may, in many systems, be shorter than the training sequence 235, since the channel model of the channel 175 established by the training sequence 235 offers some information about the channel 175 even if it has acquired some cumulative error 360. For instance, in systems where the initial training sequence 235 comprises an analog sequence for coarse characterization of the channel 175 and a digital sequence for detailed adjustment of the channel model, it may be sufficient to use only the digital sequence in the incremental training sequence 336. The characterization of the channel 175 by the fixed device 100 allows the cumulative error 360 to be restored to substantially zero at the end of the incremental training sequence 336.

After the incremental training sequence 336 is completed, the second segment 354 of the packet 250 is transmitted. During the transmission of the second segment 354, the cumulative error 360 again increases. If the actual coherence time of the channel 175 is still greater than the ART 395, the cumulative error 360 will remain less than the error threshold 200 until the completion of the second segment 354 of the data packet 250. After the second segment 354 is complete, the incremental training sequence 336 is transmitted again, allowing the fixed device 100 to characterize the channel 175 such that the cumulative error 360 in the channel model is again substantially zero.

Finally, the final segment 356 of the data packet is transmitted. Since the final segment 356 completes the transmission of the data packet 250, it is not necessary to transmit any further training sequences until another packet is transmitted. If the actual coherence time 275 is greater than the ART 395, the cumulative error 360 will remain below the error threshold 200 throughout the transmission of the packet and the fixed device 100 will correctly decode the data packet 250 from the successfully received segments 352, 354, 356.

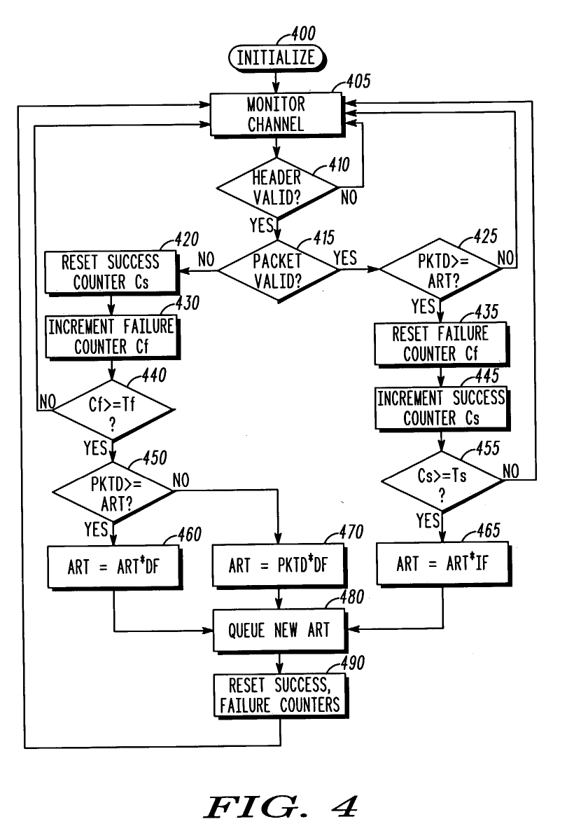

In the event that the actual coherence time 275 is still shorter than the ART 395, the ART 395 may be further reduced and the process repeated until the message is successfully decoded or a preset lower limit on the ART 395 is reached. Similarly, to allow the restoration of the original equalization signaling when channel conditions improve, the ART 395 may be increased when some threshold of packet success is reached. This iterative process is shown in FIG. 4 as described below. In any case, since the channel 175 is likely to be substantially symmetrical in both directions, the fixed device 100 should also, when sending data packets to the mobile device 160, break the data packets into data blocks less than the ART 395 and insert incremental training sequences 266 between data blocks.

Although in the preferred embodiment the equalization signaling is modified by the addition of the incremental training sequences 336, there are a number of other methods to modify the equalization signaling. For instance, additional sub-channels may be dynamically dedicated to pilots, thereby extending the actual coherence time of the channel. Inserting additional pilots in the place of payload is simply another way to trade payload bandwidth for improved reliability. Efficiency may be traded for backward compatibility by eliminating the incremental training sequence 336 and simply setting the maximum duration 240 of packet 250 to be less than or equal to the actual coherence time 275 of the channel 175. Shortening the maximum duration 240 of packet 250 results in messages being transmitted as a larger number of shorter packets, and implicitly modifies the equalization signaling by adding additional training sequences, as each packet has its own training sequence. An alternative to adding more equalization signal is to increase the power of the existing equalization signals in relation to the data signals. By increasing the power of the equalization signals, there is more equalization per transmitted data bit, and the channel characterization can be more accurate.

The coherence time 275 of the channel 175 may be estimated by the fixed device 100 in a number of ways, including packet success rate, block success rate, and rate of change of equalization parameters based on existing equalization signaling. In more sophisticated systems, measurements of such parameters as bit error rate, decision confidence level, and divergence of decoded symbols from ideal values may be taken at various times during the transmission of the data packet 250 to determine the rate of change of channel conditions depending on the physical and logical protocols in use. For the purposes of simplicity, the universally applicable method of trial and error will be described in the preferred embodiment. The preferred embodiment uses the packet success rate as indicative of the channel quality, but in a system where packets consist of multiple independently encoded blocks, the success rate of blocks could be used instead.

Referring now to FIG. 4, additional details pertaining to the operational state of the fixed device 100 in the above description according to the present invention throughout the process of maintaining the ART 395 are discussed by way of an example as follows. For purposes of illustration, it will be assumed that an AP 100 is the controlling device that determines and sets the signaling parameters on the channel, and the mobile devices 160 respond to the commands of the AP 100. It will be apparent to those skilled in the art that both of these roles may be performed by any or all devices involved in a communication, whether mobile, portable, fixed, or in any other mode.

The ART 395 and other retained values and state information in FIG. 4 are maintained independently for each mobile device 160 with which the AP 100 herein described communicates, as the states and values may be different for different devices and channels. FIG. 4 describes the operation of a single state machine representing the state of the communication channel with a single mobile device 160. When the AP 100 initializes a connection with a mobile device 160 at step 400, the ART is set to a default value greater than or equal to the assumed coherence time, and has no effect on the system, since, in this example, the system design assures that no transmitted packet would exceed this default ART in any case. Since the system specification should ensure that all compliant packets will have durations less than or equal to the assumed coherence time, there is no need to inform the mobile device of the default ART value. The success and failure counters, Cₛ and C_{f}, are set to zero. In its idle state 405, the AP 100 tests for the existence of a data packet from the mobile device. If none has been detected, control is returned to the AP 100 operating system.

When a packet header containing the address of the mobile device 160 is detected, the AP 100 tests the header at step 410. The header test 410 verifies the validity of the header data. If the header data is found to be invalid, it is possible that the identity of the mobile device is in error. Since the values, states, and counters are specific to a particular mobile device, no action is taken and the machine returns to the idle state.

If the headers are valid, a test 415 of the packet validity is performed. If the packet is invalid, it may be due to the ART being set to a value too high for the channel. In this case, the success counter Cₛ (which measures the number of consecutive successful packets detected) is reset (e.g., set to zero) in step 420, and the failure counter C_{f} (which measures the number of consecutive failed packets detected) is incremented (e.g., increased by one) in step 430.

To maintain some stability in the system, it is preferred not to change the ART in response to a single failed packet. In the preferred embodiment of the present invention, the failure counter C_{f} is tested in step 440 to determine if it has reached a threshold T_{f}, the threshold T_{f} having been specified as a system design parameter. If C_{f} is less than T_{f}, the threshold has not been reached and no further action will be taken. If C_{f} is equal to or greater than T_{f}, the ART will be reduced in an attempt to improve the performance of the channel.

In step 450, the duration of the data packet (“PKTD”) is compared to the ART to determine which factor resulted in the failure. If the duration of the data packet is greater than the ART, the cumulative error is assumed to have reached the error threshold before the incremental training sequence was sent. In this case, the current ART is multiplied at step 460 by a decrease factor, which is greater than zero and preferably less than one, to provide a new and lower ART. If, on the other hand, the ART is greater than the duration of the data packet, the cumulative error is assumed to have reached the error threshold before the end of the packet. In this case, no matter what the current value of the ART, the correct value for the ART should be lower than the duration of the failed data packet, and a new ART is calculated at step 470 by multiplying the duration of the data packet by the decrease factor D_{f}.

After a new, lower value for the ART has been calculated at either step 460 or step 470, that value is queued for transmission to the mobile device at step 480, and the success and failure counters are reset at step 490. The AP device 100 then returns to the idle state 305 to wait for the next transmission. When the mobile device 160 decodes the new ART, it will attempt to retransmit the failed packet with the new ART. If the new ART is still too high, the process will be repeated.

Although the steps above describe how to ensure that the ART is sufficiently low to ensure successful communications between a fixed device 100 and a mobile device 160, it is also desirable that ART is not lower than necessary. When channel conditions improve, a means of restoring the ART to a higher value should be provided to restore the default channel efficiency. If the test for packet validity succeeds at step 415, the duration of the data packet is tested to see if it is greater than the ART at step 425. This test is intended to eliminate the influence of shorter packets on the decision process, since success with shorter packets is probable even if the ART is too high. Further, only packets with duration greater than or equal to the ART provide evidence that the ART may be too conservative; the success of shorter packets is expected in any case. Therefore, if the test 425 fails (indicating that the duration of the data packet was lower than the ART) the result is ignored. If the test 425 succeeds, indicating that the duration of the data packet was greater than or equal to the ART, and thus the packet succeeded with training sequences separated by a time equal to the ART, the failure counter, C_{f}, is reset at step 435 and the success counter, Cₛ, is incremented at step 445.

The success counter, Cₛ, is compared to the success threshold Tₛ in step 455, since a single successful transmission is typically of little statistical significance in characterizing the channel. Increasing the ART is preferably done conservatively to ensure that the packet error rate remains low. The success threshold, Tₛ, then, may be set at a value on the order of, for example, 10 to 30, depending on other system design and performance parameters.

If the success counter, Cₛ, has not yet reached the success threshold, Tₛ, no action is taken and the state machine returns to the idle state 405. If the success counter, Cₛ, is greater than or equal to the success threshold, Tₛ, it may be safe to increase the ART for that channel to improve efficiency. In this case, the ART is increased by multiplying it in step 465 by an increase factor that is greater than one. The new ART is queued for transmission to the mobile device at step 480, and the success and failure counters are reset at step 490. The AP returns to its idle state 405 to await further transmissions. Note that, although the data packet was in this case received correctly and does not need to be retransmitted, a retransmit may be specified at the option of the system designer if desired for an immediate test of the new ART with a non-critical data packet.

It should be noted that the preferred embodiment described herein is only one possible method of implementing the present invention. Specific implementations may provide methods as described above for measurement of the actual coherence time of a channel or sub-channel. Methods of determining a suitable value for ART include, but are not limited to: setting the ART to an estimated value of the actual coherence time of the channel, with or without compensation for short-term channel variation, choosing the ART from a discrete list of values, and performing binary or other incremental searches for optimum values of the ART. If another equalization signaling parameter, such as number of pilots, is chosen for adjustment, similar options will present themselves; for instance, the actual coherence time of selected sub-channels may be measured, and the number and location of pilots chosen such that sub-channels represented by a pilot exhibit an actual coherence time greater than or equal to the assumed coherence time of the system. Alternatively, pilot spacing may be established on a trial-and-error basis similar to that described in the discussion of FIG. 4. Each of these techniques and methods may be parameterized and implemented in numerous ways depending on the specific characteristics and requirements of the system.

While the invention has been described in conjunction with specific embodiments thereof, additional advantages and modifications will readily occur to those skilled in the art. The invention, in its broader aspects, is therefore not limited to the specific details, representative apparatus, and illustrative examples shown and described. Various alterations, modifications and variations will be apparent to those skilled in the art in light of the foregoing description. Thus, it should be understood that the invention is not limited by the foregoing description, but embraces all such alterations, modifications and variations in accordance with the spirit and scope of the appended claims.

We claim:

1. In a system that uses equalization signaling to determine at least one equalization parameter representative of at least one property of a channel, a method comprising the steps of:
receiving a signal on the channel;
estimating a rate of change of the at least one property of the channel; and
adjusting the equalization signaling based on the rate of change of the at least one property of the channel.

2. The method of claim 1 wherein the rate of change of the at least one property of the channel is represented by an estimated coherence time, wherein the estimated coherence time represents a duration for which a measurement of the at least one property of the channel substantially represents the at least one property of the channel.

3. The method of claim 2 wherein the estimated coherence time is estimated by analysis of at least one of: packet success rate, block success rate, bit error rate, decision confidence level, divergence of decoded symbols from ideal values, and rate of change of equalization parameters based on existing equalization signaling.

4. The method of claim 1 wherein the step of adjusting the equalization signaling comprises transmitting additional training sequences.

5. The method of claim 1 wherein the step of adjusting the equalization signaling comprises transmitting an alternative training sequence.

6. The method of claim 1 wherein the step of adjusting the equalization signaling comprises reducing a maximum duration of a packet.

7. The method of claim 1 wherein the step of adjusting the equalization signaling comprises increasing the number of pilot sub-channels.

8. The method of claim 1 wherein the step of adjusting the equalization signaling comprises increasing the number of pilot symbols.

9. The method of claim 1 wherein the step of adjusting the equalization signaling comprises the step of increasing energy of at least one pilot symbol.

10. The method of claim 1 wherein the at least one property is selected from a group consisting of: gain, channel attenuation, phase, differential gain, differential phase, noise level, signal-to-noise ratio, multipath, fading, frequency offset, and frequency error.

11. The method of claim 1 wherein the equalization signaling comprises at least one of: training sequences, incremental training sequences, pilot sub-channels, and pilot symbols.

12. In a system that uses at least one training sequence to determine at least one equalization parameter representative of at least one property of a channel, a method comprising the steps of:
receiving a first transmission on the channel;
estimating a rate of change of the at least one property of the channel; and
adding at least one incremental training sequence to at least a second transmission based on the rate of change of the at least one property of the channel, wherein the at least second transmission is divided into a plurality of blocks and wherein the incremental training sequence is embedded between blocks of the second transmission.

13. The method of claim 12 wherein the rate of change of the at least one property of the channel is represented by an estimated coherence time, wherein the estimated coherence time represents a duration for which a measurement of the at least one property of the channel substantially represents the at least one property of the channel.

14. The method of claim 13 wherein the estimated coherence time is estimated by analysis of at least one of: packet success rate, block success rate, bit error rate, decision confidence level, divergence of decoded symbols from ideal values, and rate of change of equalization parameters based on existing equalization signaling.

15. The method of claim 12 wherein the at least one incremental training sequence comprises a subset of the at least one training sequence.

16. The method of claim 12 wherein the incremental training sequence is substantially similar to the training sequence

17. The method of claim 12 wherein the at least one property is selected from a group consisting of: gain, channel attenuation, phase, differential gain, differential phase, noise level, signal-to-noise ratio, mutlipath, fading, frequency offset, and frequency error.
